(19) United States
(12) Patent Application Publication
(10) Pub. No.: US 2013/0292568 A1
(43) Pub. Date: Nov. 7, 2013

(54) SCANNING ELECTRON MICROSCOPE AND LENGTH MEASURING METHOD USING THE SAME

(71) Applicants: Daisuke Bizen, Kokubunji (JP); Hiroshi Makino, Chino (JP); Junichi Tanaka, Hachioji (JP); Makoto Ezumi, Mito (JP)

(72) Inventors: Daisuke Bizen, Kokubunji (JP); Hiroshi Makino, Chino (JP); Junichi Tanaka, Hachioji (JP); Makoto Ezumi, Mito (JP)

(21) Appl. No.: 13/993,829

(22) PCT Filed: Dec. 5, 2011
(86) PCT No.: PCT/JP2011/078013

§ 371 Date: Jul. 24, 2013

(30) Foreign Application Priority Data
Dec. 16, 2010 (JP) 2010-280517

(51) Int. Cl. H01J 37/05; H01J 37/10

(52) U.S. Cl. CPC H01J 37/05; H01J 37/10
USPC 250/307; 250/311

(57) ABSTRACT

This electron scanning microscope comprises an electron source (102), electron optical systems (109, 110, 111) for exposing a sample (113) to primary electron beams (138), an electron detector (127) for detecting signal electrons (139) emitted from the sample, and a deceleration electrical field-type energy filter (108). The deceleration electrical field-type energy filter has a conductor thin film (304) for distinguishing the energy of signal electrons. With this configuration, it is possible to realize a scanning electron microscope having a deceleration electrical field-type energy filter with which high energy resolution is obtained, even in a case where the scanning electron microscope has a retarding optical system.

### TECHNICAL FIELD

The present invention relates to a scanning electron microscope (hereinafter described as SEM), and a length measuring method using it.

### BACKGROUND ART

Currently, a technology for measuring the dimensions of a circuit pattern formed on a wafer in the middle of a process plays an important role in the production line of a semiconductor. Conventionally, this measurement technology was mostly those based on optical microscopes. In recent years, however, a measuring device (hereinafter described as an SEM type length measuring device) based on the SEM has been widely prevalent with miniaturization of a semiconductor pattern.

At present, however, the 3d-rendering of the semiconductor device and the diversification of materials used are in progress. With the progress, there has been an increasing demand for the measurement of the dimensions of a three-dimensional device and a local elementary analysis.

As a means for satisfying this demand, there may be mentioned a method of energy-discriminating signal electrons detected in SEM (for example, Non-Patent Document 1).

Devices used in applications that energy-discriminate signal electrons are generically called energy filters. A patent related to an energy filter (hereinafter described as a deceleration electrical field-type energy filter) for applying a voltage to a metal grid and allowing only electrons having an energy of the applied voltage or more has been devised so far (for example, Patent Document 1 and Patent Document 2).

### PRIOR ART DOCUMENT

### Patent Document

Patent Document 1: Japanese Patent Publication Laid-Open No. Sho 60-240047
Patent Document 2: International Publication No. WO 01/075929

### Non-Patent Document

Non-Patent Document 1: C. Schonjahn et al., “Energy-filtered imaging in a field-emission electron microscope for dopant mapping in semiconductors”, J. Appl. Phys. 92, 7667 (2002).

### SUMMARY OF THE INVENTION

### Problems that the Invention is to Solve

Signal electrons detected in SEM are classified into secondary electrons, backscattered electrons, and Auger electrons. It is expected that discrimination of the signal electrons is effective in performing dimensional measurement of three-dimensional devices and a local elemental analysis.

This is because for high energy, the backscattered electrons are expected to be escapable from the bottom of the three-dimensional device and useful for the observation of the bottom portion. Further, the energy of Auger electrons is specific to each element, and the occurrence thereof is also limited to the extremely surface of a sample. The local elementary analysis is possible by the detection of the Auger electrons. On the other hand, the secondary electrons are electrons generally used for image formation in the scanning electron microscope. Since they are generated form the sample surface, information that reflects the shape of the sample is obtained.

As an energy filter to discriminate the signal electrons, there have heretofore been often used two types: a deceleration electrical field type that applies a voltage to the metal grid or the like and causes only electrons having an energy of the applied voltage or more to pass, and a deflection type that deflects electrons by the electromagnetic field and discriminates them by the difference of the electron orbit. Further, there has also been devised a thin film transmissive energy filter using the fact that the depth of penetration of the electrons into the material varies depending on the energy of the electrons.

The deflection type energy filter can obtain energy resolution better than the deceleration electrical field type. A problem however arises in that in addition to that the device becomes large in scale, the signal strength is weak because only the energy range of a small fraction is detected (band-pass). The thin-film transmission type has a problem that since the energy of the transmissible signal electrons is determined by the thickness of the thin film, arbitrary energy discrimination is not possible.

When the signal strength is weak, the S/N of the image is degraded and integrating the image is needed. The above energy filter is therefore not suitable for the SEM type length measuring device that needs high throughput. It is necessary for the SEM type length measuring device to change the secondary electrons and backscattered electrons detected, depending on the sample to be measured. Therefore, an energy filter that cannot perform arbitrary energy discrimination is also unsuitable for the SEM type length measuring device in like manner.

The deceleration electrical field-type energy filter is superior to the deflection type in terms of the signal strength because the energy filter allows all of the electrons having an energy larger than or equal to the threshold value to penetrate, and is superior to the thin-film transmission type in that the user can freely determine the threshold value. On the other hand, there is a problem that the deceleration electrical field-type energy filter is inferior to the deflection type in energy resolution.

The principle and problems of the conventional deceleration electrical field-type energy filter will hereinafter be described using FIG. 2.

The deceleration electrical field-type energy filter is composed of an energy filter power supply 126 connected to a conductor grid 201 and a grid as shown in FIG. 2. When a negative voltage VF is applied to the conductor grid 201 by the energy filter power supply 126, such a potential barrier as shown in an equipotential line (equipotential surface) 202 is formed.

When a wafer (sample) 113 is irradiated with primary electrons, signal electrons 139 including secondary electrons, backscattered electrons and Auger electrons are emitted from the wafer 113. Thereafter, of the signal electrons 139 incident on the energy filter, only the electrons having an energy exceeding the potential barrier pass through the energy filter and are detected.

There has currently been often adopted a retarding method that in the SEM type length measuring device, applies a negative voltage Vr of a few kV to the wafer 113 by a retarding power supply 121 and decelerates the primary electrons 138 immediately before the wafer. In the retarding method, the signal electrons 139 emitted from the wafer 113 have a feature that they are accelerated by the negative voltage Vr of the few kV applied to the wafer 113. Therefore, when the retarding method and the deceleration electrical field-type energy filter are used in combination, the signal electrons 139 enter an energy filter 108 with an energy of a few keV. In this case, there is a need to apply a voltage of a few −kV to the energy filter power supply 126 to energy-discriminate the signal electrons 139.

On the other hand, in the deceleration electrical field-type energy filter, the potential of the grid central portion becomes lower than the voltage VF applied to the conductor grid 201. In addition to that the energy resolution of the energy filter is degraded as the amount of the voltage drop becomes large, the voltage drop amount is proportional to VF. That is, due to the voltage drop in the grid central portion, the energy resolution is also degraded as VF becomes larger in the deceleration electrical field-type energy filter. Therefore, the compatibility of the retarding method and the high energy resolution has been difficult until now.

An object of the present invention is to provide a scanning electron microscope equipped with a deceleration electrical field-type energy filter capable of high energy resolution even if it has a retarding optical system, and a length measuring method using the same.

### Means for Solving the Problems

As one embodiment for achieving the above object, there is provided a scanning electron microscope having an electron source, a deflector for deflecting a primary electron beam emitted from the electron source, a converging lens for converging the primary electron beam deflected by the deflector, an electron detector for detecting signal electrons emitted due to irradiation of a sample with the primary electron beam converted by the condenser lens, and a deceleration electrical field-type energy filter which is placed on the sample side than the electron detector and discriminates the energy of the signal electrons, characterized in that the deceleration electrical field-type energy filter has a conductor thin film for energy discrimination of the signal electrons.

In the above scanning electron microscope, there is further provided a length measuring method using a scanning electron microscope equipped with an image processing circuit which forms a difference image between a first scan image obtained in a state in which a first set voltage is applied to the conductor thin film and a second scan image obtained in a state in which a second set voltage is applied to the conductor thin film. The length measuring method is characterized by including a step of applying a first voltage to the conductor thin film and obtaining a first image, based on the signal electrons energy-discriminated at the first voltage, a step of applying a second voltage to the conductor thin film and obtaining a second image, based on the signal electrons energy-discriminated at the second voltage, a step of forming a difference image between the first image and the second image, and a step of measuring a pattern dimension of the sample from the difference image, and in that the difference image is formed by Auger electrons of the sample.

### Effects of the Invention

By using a conductor thin film in a deceleration electrical field-type energy filter, there can be provided a scanning electron microscope equipped with the deceleration electrical field-type energy filter capable of obtaining high energy resolution even if it has a retarding optical system, and a length measuring method using the same.

### BRIEF DESCRIPTION OF THE DRAWINGS

FIG. 1 is a schematic overall configuration diagram of a scanning electron microscope (SEM type length measuring device) according to a first embodiment.

FIG. 2 is a schematic configuration diagram for describing the operation of a conventional deceleration electrical field-type energy filter.

FIG. 3 is a schematic configuration diagram for describing the operation of a deceleration electrical field-type energy filter in the scanning electron microscope according to the first embodiment.

FIG. 4 is a graph of the number of filter-transmitted electrons (S curve) relative to the voltage applied to a grid, for describing the difference between energy resolutions of the energy filters shown in FIGS. 2 and 3.

FIG. 5 is a graph of the number of signal electrons relative to the energy of the signal electrons, which are detected by each of the energy filters shown in FIGS. 2 and 3.

FIG. 6 is a diagram for describing a method of measuring the difference in potential between a conductor pattern and an insulator pattern at the exposure of primary electrons.

FIG. 7 is a diagram showing one example of energy distributions that the signal electrons outputted from the conductor pattern and the insulator pattern have.

FIG. 8 is a graph of the filter transmitted number (S curves) of signal electrons outputted from each of the conductor pattern and the insulator pattern, relative to the voltage applied to a grid.

FIG. 9 is a graph of the number of signal electrons relative to the energy of the signal electrons, for describing a bandpass detection.

FIG. 10 is a schematic configuration sectional view of the deceleration electrical field-type energy filter using a conductor thin film employed in the scanning electron microscope according to the first embodiment.

FIG. 11 is a flowchart showing a recipe creating procedure for length measurement according to a second embodiment.

FIG. 12 is a diagram showing one example of a GUI screen for setting conditions of a deceleration electrical field-type energy filter used in a scanning electron microscope (SEM type length measuring device) according to the second embodiment.

FIG. 13 is a flowchart showing a procedure for setting the deceleration electrical field-type energy filter used in the scanning electron microscope according to the second embodiment.

FIG. 14 is a flow diagram showing an image acquisition/processing procedure in the scanning electron microscope according to the second embodiment.

FIG. 15 is a flow diagram showing a length measurement procedure according to the second embodiment.

FIG. 16 is a schematic fragmentary configuration diagram of a scanning electron microscope (SEM type length measuring device) according to a third embodiment.

FIG. 17 is a schematic overall configuration diagram of a scanning electron microscope (SEM type length measuring device) according to a fourth embodiment.

FIG. 18 is a perspective view of the deceleration electrical field-type energy filter shown in FIG. 10.

### MODE FOR CARRYING OUT THE INVENTION

Modes for carrying out the present invention will hereinafter be described in detail with reference to the drawings.

The present embodiment is characterized in that a conductor thin film whose thickness is greater than or equal to 100 Å and less than or equal to 500 Å (greater than or equal to 10 nm and less than or equal to 50 nm) is attached to each grid of a conventional deceleration electrical field-type energy filter, and a negative voltage is applied to the grid to distinguish the energy of signal electrons. According to the present embodiment, an SEM using a retarding method is capable of obtaining energy resolution more excellent than the conventional deceleration electrical field-type energy filter. A description will be made below of the reason why the energy resolution more excellent than the conventional deceleration electrical field-type energy filter can be obtained by using the conductor thin film.

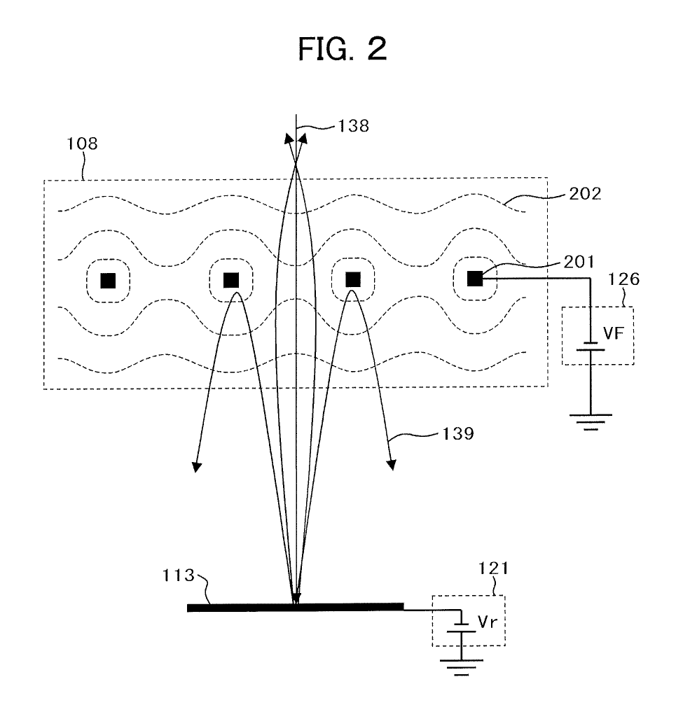

First, in the conventional deceleration electrical field-type energy filter, the potential of a grid central portion becomes lower than a voltage VF (<0) applied to a conductor grid 201 (FIG. 2). With the influence of this potential drop, even electrons each having energy lower than −VF can pass through the energy filter. The energy resolution is therefore degraded.

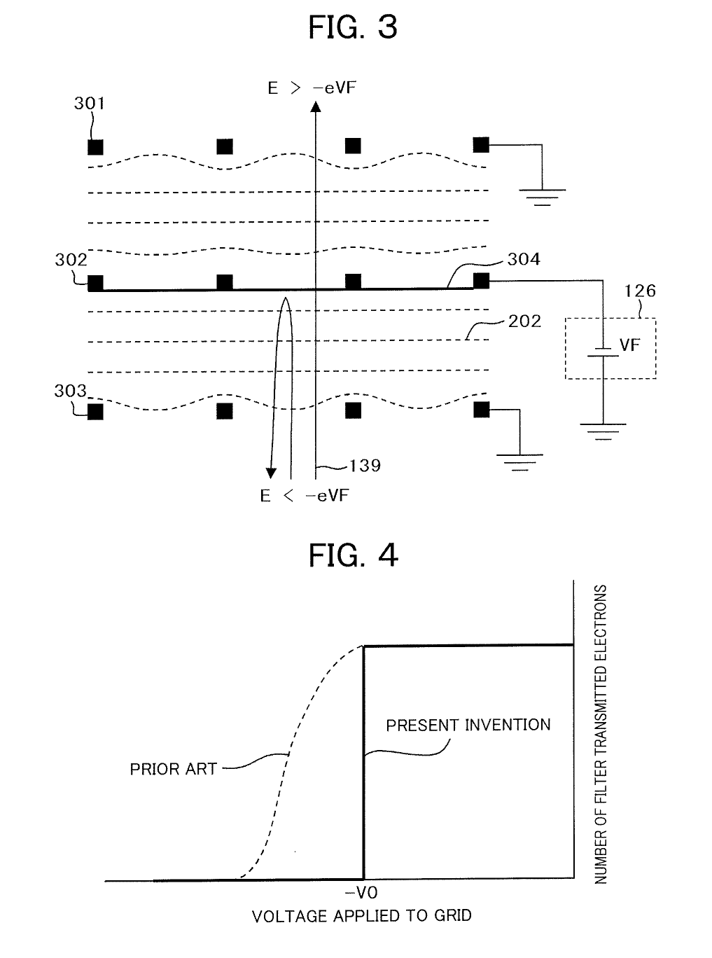

Although will be explained later in detail, in the present embodiment, a conductor thin film 304 is attached to each of conductor grids 302 to which a voltage is applied (FIG. 3). When the conductor thin film 304 is attached to the conductor grid 302 and a voltage VF (<0) is applied from an energy filter power supply 126, equipotential lines 202 are formed substantially parallel to the conductor thin film 304 as shown in FIG. 3. In particular, by pasting the conductor thin film 304 to the signal electron incoming side of the conductor grids 302, the equipotential lines 202 are formed more parallel to the conductor thin film 304 on the signal electron incoming side. In this case, the potential drop at the grid central portion, which has occurred in the conventional deceleration electrical field-type energy filter (FIG. 2), is eliminated, and a substantially uniform potential barrier of the applied voltage VF is formed.

A description will next be made of the difference between signal transmittance properties of the energy filter shown in FIG. 3 and the conventional energy filter.

Now consider where electrons each having an energy of V0 (>0) are applied to both of the deceleration electrical field-type energy filter using the conductor thin film and the conventional energy filter in a range sufficiently wider than the pitches of the conductor grids 201, 301, 302 and 303. At this time, how the number of electrodes passing through the filters change with respect to the voltage VF applied to the conductor grids 201 and 302 is shown in FIG. 4. Generally, the curve shown in FIG. 4 is called an S curve.

In the conventional energy filter, a predetermined number of electrons penetrate due to the above-described influence of potential drop even in a state in which a voltage higher than −V0 is applied (broken line in FIG. 4). Thus, the energy resolution is degraded.

On the other hand, since the potential drop becomes as small as negligible when the conductor thin film 304 is attached to the conductor grid 302, the S curve shows a behavior close to a step function (solid line in FIG. 4). The energy resolution is improved larger than the conventional energy filter. Here, the energy resolution is defined by the width of the rise of the S curve, and the energy resolution is assumed to be good as the width is narrow.

A description will next be made of advantages obtained where a sample is observed using the deceleration electrical field-type energy filter using the conductor thin film.

The deceleration electrical field-type energy filter is a so-called bypass filter which has the property for allowing all of the electrons having energy capable of passing through the potential barrier formed by the voltage applied to each grid to pass.

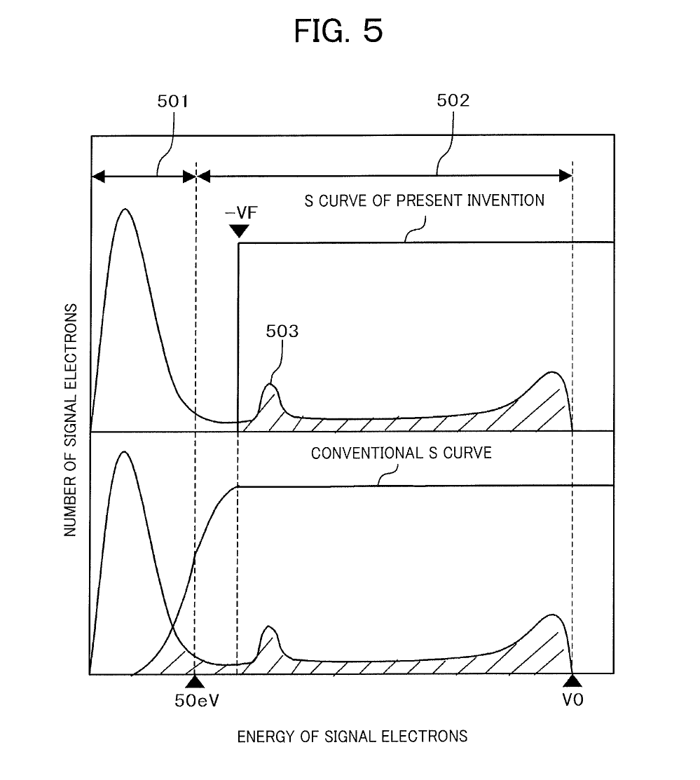

When a primary electron enter the sample with an energy of V0, the energy dependence of the number of signal electrons emitted from the sample is generally represented by FIG. 5. Of the signal electrons, those having an energy of 0 to 50 eV are called secondary electrons 501, and those having an energy of 50 eV or more are called backscattered electrons 502. Auger electrons 503 are electrons emitted due to the excitation of each inner shell electrons of atoms, and the energy thereof is atom-specific. Generally, when a scan image is formed with only the secondary electrons 501, an image on which the shape of the surface of the sample has been reflected is obtained. When a scan image is formed with only the backscattered electrons 502, an image on which the inside of the sample and the difference in element number have been reflected, is obtained.

Now compare the cases where the signal electrons represented by the spectrum of FIG. 5 are subjected to filtering by the deceleration electrical field-type energy filter using the conductor thin film and the conventional type. When the voltage VF (<0) is applied to the deceleration electrical field-type energy filter using the conductor thin film, only electrons having an energy of −VF or more can pass through the energy filter (upper diagonally-shaded area in FIG. 5). On the other hand, since the conventional energy filter is inferior in energy resolution to the present invention, electrons having an energy of −VF or less also pass through the energy filter (lower diagonally-shaped area in FIG. 5). In this case, electrons of other than the targeted energy are also detected.

The deceleration electrical field-type energy filter using the conductor thin film makes it possible to detect only electrons having an energy of the voltage or more applied to the filter. This effect is effective in, for example, detecting one having an energy of near V0 even among the backscattered electrons or detecting one having an energy of 10 eV or more even among the secondary electrons.

A description will next be made of an effect at the time that the difference in potential at a sample is measured using the deceleration electrical field-type energy filter using the conductor thin film.

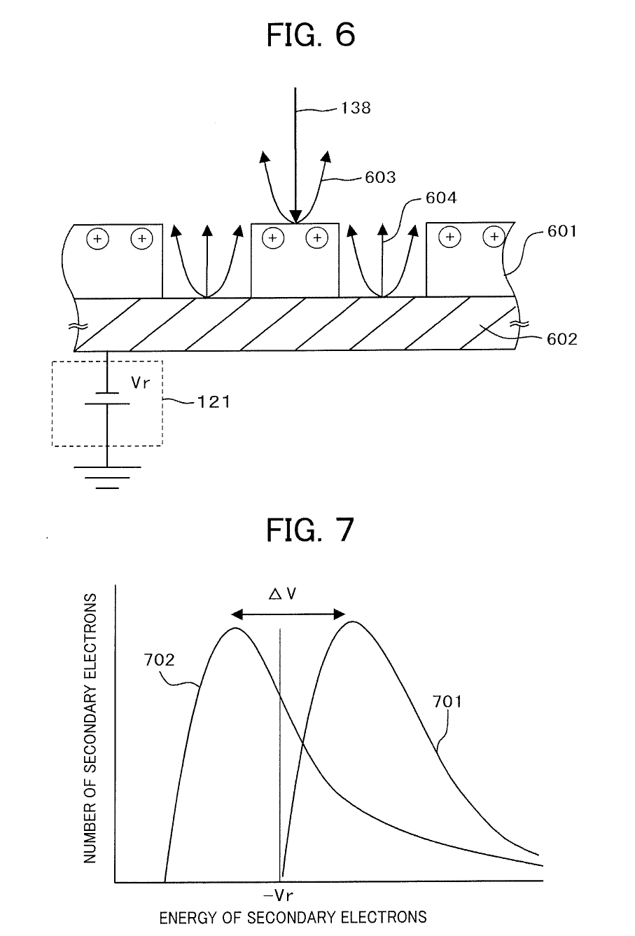

A description will be made below of a method for measuring a difference in potential between a conductor 602 and an insulator 601 when each insulator 601 pattern is placed on a sample of the conductor 602 as shown in FIG. 6. Here, the conductor 602 is connected to a retarding power supply 121 for applying a potential Vr (<0) for decelerating primary electrons 138 immediately before the sample.

When the insulator 601 is irradiated with the primary electrons 138, the insulator 601 is electrostatically charged. The positive and negative signs of electrostatic charge is determined by secondary electron generation efficiency defined by (the amount of secondary electrons)/(the amount of primary electrons). If the secondary electron generation efficiency is smaller than 1.0, then the insulator 601 is negatively charged. If the secondary electron generation efficiency is larger than 1.0, then the insulator 601 is positively charged. The secondary electron generation efficiency is determined by the energy at the incident time of the primary electrons 138. The secondary electron generation efficiency of an insulation material commonly used in a semiconductor device exceeds 1.0 when the energy ranges from 500 eV to 1000 eV.

A description will be made below of the case where the insulator 601 is positively charged. First, the secondary electrons 604 emitted from the conductor 602 are accelerated by the retarding voltage Vr and have an energy of −Vr when they enter the energy filter. They therefore become a distribution designated at numeral 701 in FIG. 7. Incidentally, FIG. 7 is a diagram showing one example illustrative of energy distributions that the signal electrons outputted from the conductor pattern and the insulator patterns have.

On the other hand, when the secondary electrons 603 emitted from the insulator 601 positively charged by ΔV enter into the energy filter, they have an energy of −Vr−ΔV. Therefore, as designated at numeral 702 in FIG. 7, the energy distribution of the number of the secondary electrons is shifted by ΔV.

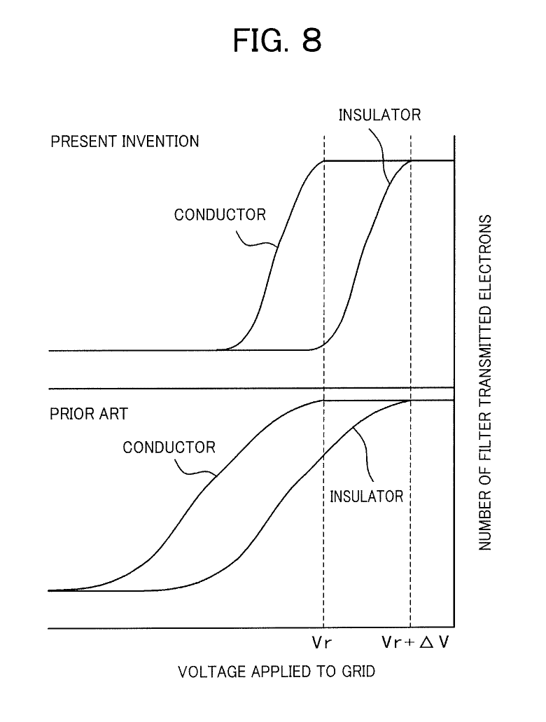

When an S curve is acquired by the deceleration electrical field-type energy filter using the conductor thin film with respect to the conductor and insulator shown in FIG. 7, it is as shown on FIG. 8. At the conductor section, the number of transmitted electrons begins to decline from Vr to the grid, but at the insulator section, the S curve is shifted by ΔV. Therefore, when the voltage close to Vr is applied to the grid, the majority of electrons that penetrate the filter and is detected, assumes the secondary electrons 604 emitted from the conductor, and an image in which only the conductor 602 is bright is obtained.

On the other hand, when an S curve is acquired by the conventional deceleration electrical field-type energy filter with respect to the conductor and insulator shown in FIG. 7, it is shown as below in FIG. 8. Although the S curve is shifted by ΔV even by the conventional energy filter, the energy resolution is poor and hence a change in the S curve is gentle. As a result, when the voltage close to Vr is applied to the grid, not only the secondary electrons 604 emitted from the conductor but also many of the secondary electrons 603 emitted from the insulator pass through the energy filter, thus resulting in the fact that there isn't so much of a difference in image brightness between the conductor 602 and the insulator 601.

Therefore, in the conventional energy filter, ΔV is increased in order to make a large difference in the image brightness between the conductor 602 and the insulator 601. That is, there was a need to increase the charge amount of the insulator 601. There can however be provided a method of making a difference in the image brightness between the conductor and the insulator by using the deceleration electrical field-type energy filter using the conductor thin film even in the case of a slight difference in potential as compared with the prior art.

A method for forming a scan image by signal electrons in an arbitrary energy range using the deceleration electrical field-type energy filter using the conductor thin film will next be explained.

The deceleration electrical field-type energy filter is of a bypass filter which allows all of the electrons having an energy of a given threshold value or above to pass therethrough. When, however, a difference image between two sheets of images obtained by applying two types of different set voltages to the grid of the filter is formed, an image created by the signal electrons in the arbitrary energy range can be formed.

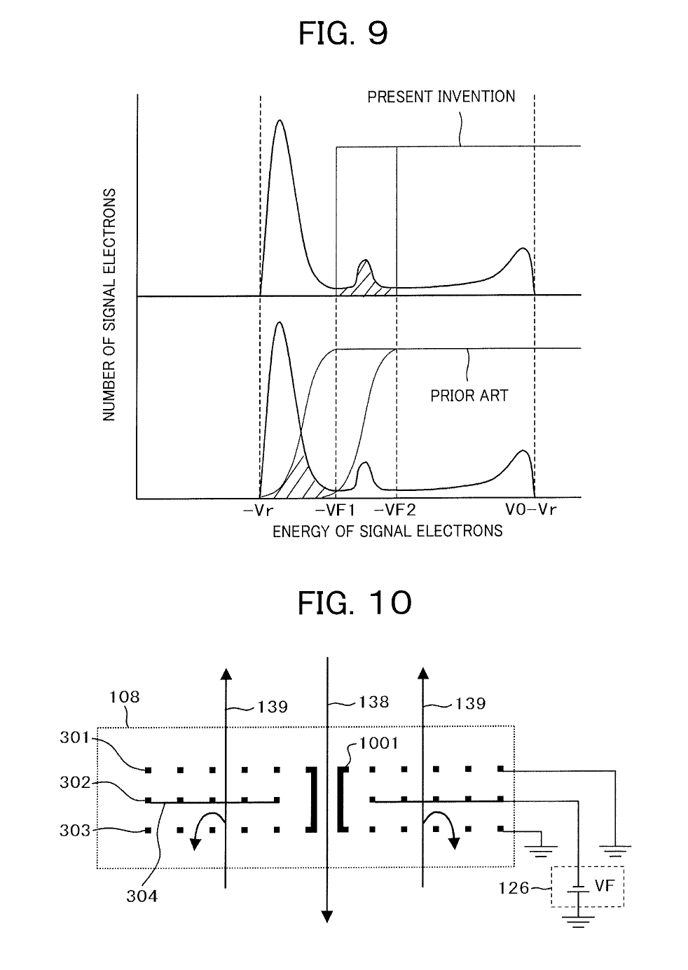

When the primary electrons accelerated at an acceleration voltage V0 in an electron source are applied to the sample connected to the retarding power supply, signal electrons emitted from the sample are accelerated by the retarding voltage Vr. The relationship between the number of signal electrons at the entrance thereof in the energy filter and the energy thereof is represented by the distributions shown in FIG. 9.

Using the deceleration electrical field-type energy filter using the conductor thin film, a first set voltage VF1 is applied to its corresponding grid of the filter at the same point of the sample, and thereafter a scan image 1 is acquired. Next, a second set voltage VF2 (<VF1) is applied and thereafter a scan image 2 is acquired. The difference image between the scan images 1 and 2 is an image created by signal electrons in an energy range from −VF1 to −VF2 as indicated by a diagonally-shaped area on FIG. 9.

On the other hand, when the difference image is obtained by the above-mentioned method using the conventional filter, it becomes an image created by signal electrons in an energy range indicated by a diagonally-shaded area placed below in FIG. 9, thus resulting in the fact that electrons in an energy region different from the setting of VF1 and VF2 get mixed. Therefore, for example, only the Auger electrons cannot be detected.

Since the deceleration electrical field-type energy filter using the conductor thin film is good in energy resolution as compared with the conventional filter, an image can be formed only by the Auger electrons, for example. Since the energy of the Auger electrons is specific to the element, a spatial distribution of micro regions of any element can be visualized by forming the scan image by the Auger electrons.

The invention will hereinafter be explained in more detail by embodiments.

### First Embodiment

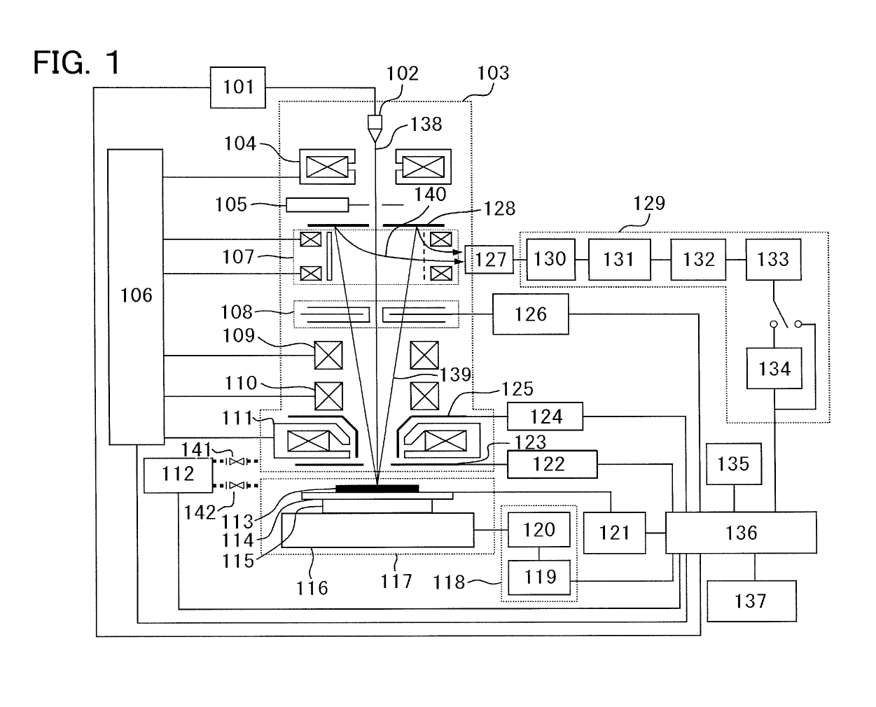

A first embodiment will be described using FIGS. 1, 10 and 18. Incidentally, matters described in the modes for carrying out the invention and not described in the present embodiment can be applied to the present embodiment. FIG. 1 is a schematic overall configuration diagram of a scanning electron microscope (SEM type length measuring device) equipped with a deceleration electrical field-type energy filter using a conductor thin film according to the present embodiment.

A basic configuration of the SEM type length measuring device of the present embodiment will hereinafter be explained. Divided broadly, the SEM type length measuring device is comprised of an SEM housing 103, a sample chamber 117, an SEM system control unit 136, a vacuum pumping system unit 112, an image forming unit 129 and a length measurement system control unit 137.

The SEM housing 103 and the sample chamber 117 perform vacuum exhaust in such a manner that a sufficient degree of vacuum is maintained to obtain a scan image by vacuum pumping devices such as a rotary pump, a dry pump, a turbo molecular pump and so on although not shown in the drawing, and a vacuum pumping system unit 112 equipped with a mechanism that controls them. The vacuum pumping system unit 112 controls the opening/closing of valves (A) 141 and (B) 142 that connects the vacuum pumping devices, the SEM housing 103 and the sample chamber 117.

### (SEM Housing and Sample Chamber)

The SEM housing 103 is made up of an irradiation system for applying a primary electron 138 to a sample and a detection system. The SEM housing 103 is comprised of an electron source 102, a condenser lens 104, an aperture 105, a reflection plate 128, a detector 127, an ExB deflector 107, an energy filter 108, deflectors 109 and 110, a booster electrode 125, an objective lens (converging lens) 111 and a trap plate electrode 123.

In the present embodiment, the deceleration electrical field-type energy filter 108 using the conductor thin film to be described later is placed directly below the ExB deflector 107 and functions as an energy filter with the conductor thin film being applied with a voltage having a negative polarity from an energy filter power supply 126 to decelerate a signal electron 139.

The primary electrons 138 emitted from the electron source 102 are converged by the condenser lens 104, pass through the aperture 105 for controlling the current of the primary electrons 138 incident on a wafer (sample), pass through holes of the reflection plate 128 and a shield pipe (whose details will be described later) of the energy filter 108 and are deflected by the deflectors 109 and 110, followed by being narrowed down by the objective lens 111 and launched into the sample.

The signal electrons 139 (secondary electrons, backscattered electrons and Auger electrons) generated due to the irradiation of the wafer 113 with the primary electrons 138 are accelerated by a negative voltage applied to a wafer holder 114 by a retarding power supply 121 and the difference in potential between the trap plate electrode 123 and the booster electrode 125 and converged by the objective lens (converging lens) 111. After the signal electrons 139 have been deflected by the deflectors 109 and 110, they pass through the energy filter 108 and impinge on the reflection plate 128.

Electrons 140 (tertiary electrons) generated by the reflection plate 128 due to the signal electrons 139 having collided with the reflection plate 128 are drawn into the detector 127 by the ExB deflector 107. While the present embodiment will explain the configuration for detecting the electrons 140 (tertiary electrons) generated by the reflection plate 128, the effect of the present invention can be obtained even though a detector capable of directly detecting the signal electrons 139, e.g., a semiconductor detector or a microchannel plate is placed in the reflection plate 128 position.

There can be obtained an effect that the signal electrons 139 are raised to the reflection plate 128 side by applying a positive voltage to the booster electrode 125 from a booster power supply 124. Further, the potential of the booster electrode 125 is prevented from leaking onto the wafer 113, and the same voltage as the retarding voltage is applied to the trap plate electrode 123 from a trap plate power supply 122 for the purpose of uniformizing charging of the wafer 113 to be charged.

The sample chamber 117 is comprised of a stage 116, an insulating material 115 and a wafer holder 114 with the wafer 113 placed thereon. The wafer holder 114 and the grounded stage 116 are electrically insulated by the insulating material 115. A voltage is adapted to be applied to the wafer holder 114 by the retarding power supply 121. Further, the wafer 113 and the wafer holder 114 are in contact with each other, and the wafer 113 and the wafer holder 114 are at the same potential. While the present embodiment will describe the case where the semiconductor wafer is observed, it can be observed by applying a voltage having a negative polarity to other samples from the retarding power supply 121.

Also, the stage 116 can be driven in the plane of the direction vertical to the central axis of the SEM housing 103. That is, if the central axis of the SEM housing 103 is assumed to be a z axis, then the stage 116 is movable in the x, y plane. The wafer holder 114 is fixed to the stage 116 through the insulating material 115 interposed therebetween and can be moved by driving the stage 116. The movement of the stage 116 is controlled by a stage controller 119 and a stage driving unit 120 in the stage control unit 118.

### (SEM System Control Unit)

A SEM system control unit 136 is connected to an electron gun power supply 101 that controls an acceleration voltage of the primary electrons 138 emitted from the electron source 102, an electron optical system control power supply 106 that controls the condenser lens 104, ExB deflector 107, deflectors 19 and 110 and objective lens (converging lens) 111, the booster power supply 124 that controls the voltage of the booster electrode 125, the trap plate power supply 122 that controls the voltage of the trap plate electrode 123, the retarding power supply 121 that controls the voltage of the wafer holder 114, the energy filter power supply 126 that controls the voltage applied to the conductor thin film, of the energy filter 108, the vacuum pumping system unit 112, the image forming unit 129, and an image display unit 135. The SEM system control unit 136 controls the above devices by sending signals.

### (Electron Optical System Control Power Supply)

The electron optical system control power supply 106 controls the current of the primary electrons 138 passing through the aperture 105 by controlling the current flowing through a coil that constitutes the condenser lens 104. Further, the electron optical system control power supply 106 controls the current of a coil constituting the ExB deflector 107 and the voltage of the electrode thereof to thereby make it possible to draw the tertiary electrons 140 into the detector 127 without deflecting them at the ExB deflector 107. Further, the electron optical system control power supply 106 controls the current flowing through coils that constitute the deflectors 109 and 110 to scan the primary electrons 138 on the wafer 113.

The electron optical system control power supply 106 controls the current flowing through a coil constituting the objective lens 111 in such a manner that the primary electrons 138 are focused on the wafer 113. This control is performed in such a manner that the primary electrons 138 are always narrowed down on the wafer 113 when the electron gun power supply 101, the booster power supply 124, the trap plate power supply 122 and the retarding power supply 121 have changed.

The energy of the primary electrons 138 incident on the wafer 113 is determined by the difference between the acceleration voltage set by the electron gun power supply 101 and the voltage (retarding voltage) applied to the wafer holder 114 by the retarding power supply 121. Changing the retarding voltage enables the energy of the primary electrons 138 incident on the wafer 113 to change.

### (Detector and Image Forming Unit)

In order to form a scan image, the primary electrons 138 are deflected by the deflectors 109 and 110 in such manner that the primary electrons 138 scan on the wafer 113. The signal of the tertiary electrons 140 captured by the detector 127 is amplified by a signal amplifier 130. Thereafter, an AD converter unit 131 converts the signal into a digital signal and sends the same to an image processing unit 132. The image processing unit 132 forms a scan image as a map of a tertiary electron signal synchronized with a scanning signal. The formed scan image is stored in an image memory unit 133.

Here, as the maximum gradation value of the formed scan image and the minimum gradation value thereof fall within a range from the minimum value of a gradation value assigned to one pixel of an image to its maximum value, the amplification factor of the signal amplifier 130 and its offset are automatically adjusted. The amplification factor and the offset can also be set by a user. The detector 127 is kept floating at a high voltage of positive polarity.

A difference processing unit 134 has a function of forming a difference image between the arbitrary two sheets of scan images stored in the image memory unit 133. Although will be described later, the difference processing unit 134 is used upon forming an image by signal electrons in an arbitrary energy range.

The scan image stored in the image memory unit 133 and the difference image formed by the difference processing unit 134 can be confirmed at any time by the user in the image display unit 135 through the SEM system control unit 136.

### (Length Measurement System Control Unit)

In the SEM type length measuring device shown in the present embodiment, the length measurement system control unit 137 stores information about the pattern and process of the wafer 113 to be length-measured, an observation condition, a measurement area, an algorithm and the like used for length measurement therein so that an optimum length measurement is performed, and is connected to the SEM system control unit 136. The SEM type length measuring device manages and controls the entire device through the SEM system control unit 136.

Thus, the SEM type length measuring device has a mechanism that performs the length measurement of the wafer 113 regardless of the presence or absence of the operator and can monitor the result of length measurement.

### (Structure of Deceleration Electrical Field-Type Energy Filter Using a Conductor Thin Film)

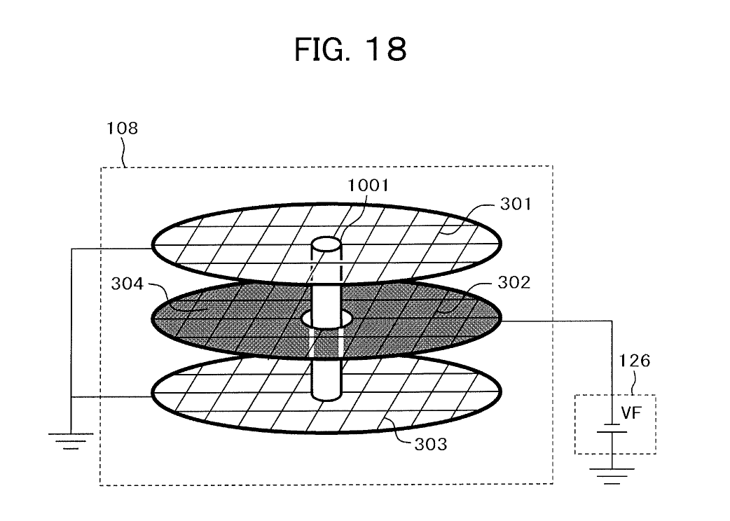

The structure of the deceleration electrical field-type energy filter 108 using the conductor thin film will next described in detail using FIGS. 10 and 18. FIG. 10 is a schematic configuration sectional view of the deceleration electrical field-type energy filter using the conductor thin film used in the scanning electron microscope according to the present embodiment. FIG. 18 is a perspective view thereof.

In the present embodiment, the energy filter 108 mounted in the SEM type length measuring device is composed of conductor grids 301, 302 and 303. The pitch of each of the conductor grids 301, 302 and 303 is the extent to which the conductor thin film is not torn and pasted with no slack, for example, −1 mm.

A description will be made below of the case in which the conductor thin film 304 is pasted only to the conductor grid 302. A conductor thin film similar to the conductor thin film 304 can however be pasted to both or one of the conductor grids 301 and 303 in addition to the conductor grid 302.

The conductor grid 302 is connected to the energy filter power supply 126 capable of applying a voltage of negative polarity, via a fieldthrough (not shown) that can maintain vacuum. In order to avoid the discharge, the conductor grid 302 is spaced −1 mm or more between the conductor grids 301 and 303 and between the conductor grids and the shield pipe 1001.

The conductor thin film 304 whose thickness is greater than or equal to 100 Å and less than or equal to 500 Å (greater than or equal to 10 nm and less than or equal to 50 nm) has been pasted to the conductor grid 302. The conductor thin film 304 has conductivity. As a conductive material, may be used, for example, conductors such as Al, Au, Cu, W, C, stainless steel, or a deposit of the above-mentioned conductors onto an insulator thin film such as SiN. These may be used singly or in combination.

Further, as the conductors to replace the conductor such as Al, Au, Cu, W, C, stainless steel, graphene can also be used. In this case, the thickness of the conductor thin film 304 becomes greater than or equal to 3 Å and less than or equal to 30 Å (greater than equal to 0.3 nm and less than or equal to 3 nm). Thinning the thickness of the conductor thin film 304 makes it possible to reduce a phenomenon that secondary electrons having an energy to be transmitted are scatted on the thin film and less likely to be detected. Further, the effect of improving an SN ratio of an SEM image can also be obtained with an improvement in the transmittance of the thin film.

The conductor thin film 304 preferably has an opening of a few μm or so for the passage of signal electrons 139. For example, as an example of the conductor thin film 304, there is cited a microgrid which is commercially available as a holding base of the sample in the transmission electron microscope. Even when the conductor thin film 304 has an opening of −μm or so, the uniformity of the potential barrier formed on the conductor grid 302 is maintained sufficiently. In the present embodiment, there was used one having an aperture rate of 80% and 10 cmφ as the dimension of the energy filter. The present invention is however not limited thereto. It is desirable that the aperture rate is as high as possible to the extent that an equielectric field is formed parallel to the conductor thin film.

Although not shown in the drawing, a description will be made of an example of a method for pasting the conductor thin film 304 to the conductor grid 302. An organic film such as collodion has been pasted to the conductor grid 302 and the conductor such as Al, Au, Cu, W, stainless steel or the like has been deposited on the above-described organic film with a thickness of greater than or equal to 100 Å and less than or equal to 500 Å, followed by being heated to fly the baked organic film, so that the conductor thin film is obtained. A conductor thin film composed principally of C is fabricated by heating the above-described single organic film.

Graphene prepared on a metal substrate of Cu, Ni or the like is transferred onto a resist such as polymethyl methacrylate (PMMA) or the like when the graphene is used as the conductor. Thereafter, the PMMA with the grapheme transferred thereto is affixed onto the conductor grid 302, and only the PMMA is removed by a resist stripping agent, so that a conductor thin film 304 can be obtained.

A negative voltage can be applied to the conductor grid 302 with the conductor thin film 304 affixed thereto from the energy filter power supply 126. A potential barrier is formed by the applied voltage, and only the signal electrons 139 having an energy higher than the potential barrier can pass through the energy filter 108.

In the present embodiment, since a negative voltage of −kV is applied to the conductor grid 302, the primary electron beam is greatly deflected as it passes through the energy filter where the deceleration electrical field-type energy filter is configured only by the conductor grid 302 and the conductor thin film 304.

By grounding the conductor grids 301 and 303 placed above and below the conductor grid 302 and connecting the shield pipe 1001 through which the primary electrons 138 pass, by the conductor grids 301 and 303, almost 0V is reached on the orbit of the primary electrons 138. The primary electrons 138 can pass through the energy filter 108 with being largely unaffected even when a voltage is applied to the energy filter.

By grounding the shield pipe 1001 through which the primary electrons 138 pass, even though a voltage is applied to the conductor grid 302, there is no effect on the beam diameter of the primary electrons 138 (spatial resolution is not degraded), and there is an effect that the positional displacement of the primary electrons 138 on the wafer 113 and the blur of the focus becomes small. Further, the diameter of the shield pipe is about 1 mm (1±0.5 mm).

By affixing the conductor thin film 304 onto the conductor grid 302 and combining the grounded shield pipe 1001 with it, a high energy resolution can be obtained. Further, even though the voltage applied from the energy filter power supply 126 is changed, there is no need to correct the misalignment and focus blur and the spatial resolution is not degraded, thereby making it possible to search an optimal applied voltage while observing the microstructure.

The above-described shield pipe 1001 has been connected to both of the conductor grids 301 and 303, but may be connected only to either of the conductor grids 301 and 303.

According to the present embodiment as described above, there can be provided a scanning electron microscope equipped with a deceleration electrical field-type energy filter, which is capable of by using the conductor thin film in the deceleration electrical field-type energy filter, significantly improving the energy resolution of a deceleration electrical field-type filter small in size and large in signal amount and obtaining high energy resolution even when a retarding optical system is provided. Providing the deceleration electrical field-type filter with a shield pipe needs not to correct misalignment of the primary electron beam and the focus blur and makes it possible to suppress the degradation of the spatial resolution.

### Second Embodiment

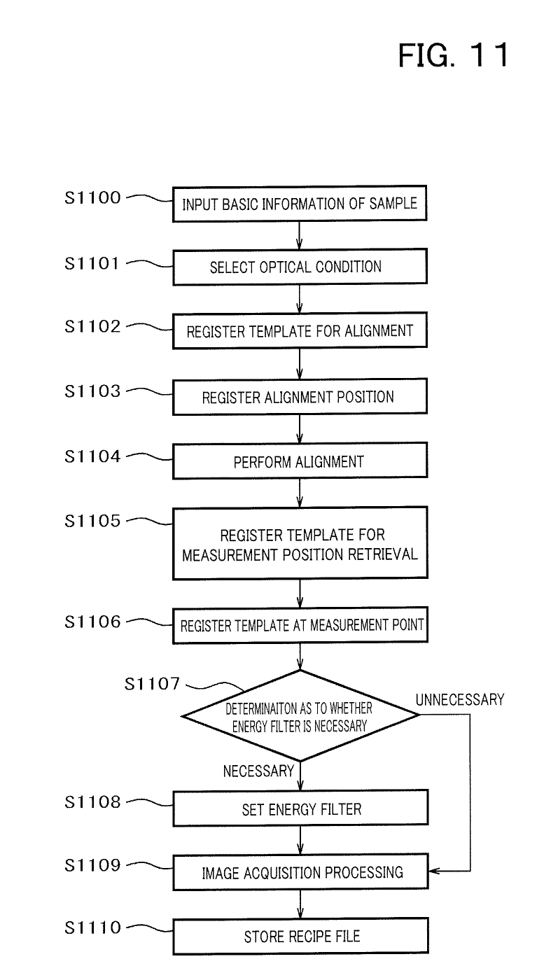

A second embodiment will be described using FIGS. 11 through 15. Incidentally, matters described in the first embodiment and not described in the present embodiment can be applied even to the present embodiment unless otherwise specified. The same reference numerals as in the first embodiment indicate the same components.

The present embodiment will describe a method of performing automatic length measurement in the SEM type length measuring device equipped with the deceleration electrical field-type energy filter using the conductor thin film described in the first embodiment.

The automatic length measurement is divided into a “process of recipe creation” by the operator and a “process of automatic length measurement” using the recipe. The respective processes will hereinafter be described. Incidentally, the recipe creation of the present embodiment is executed on the SEM type length measuring device shown in FIG. 1. Each of the processes from the recipe creation to the automatic length measurement is governed by the length measurement system control unit 137 in its entirety. Although not shown in FIG. 1, in the SEM type length measuring device used in the present embodiment, an external server is connected to the length measurement system control unit 137 or the image display unit 135, and information large in data size such as recipe information is stored in the external server. Furthermore, the length measurement system control unit 137 or the image display unit 135 is provided with a communication function depending on whether to connect to the server. Here, the communication function means, for example, software for controlling communication processing, a computer for executing the software, or such as a terminal for connecting to a communication line, but in the following description, a function implemented by communication processing software may be referred to as a communication function.

### “Process of Recipe Creation”

A procedure for creating the recipe is shown using FIG. 11.

### (Input Step S1100 of Basic Information of Sample)

First, an operation who intends to perform length measurement of the sample inputs information of the sample to be length-measured. The device operator inputs information while viewing the input screen shown in the image display unit 135, for example. Here, when the sample is of, for example, semiconductor wafers, the variety of the wafers, and the name of the manufacturing process correspond to the aforementioned information. These pieces of information entered by the operator are used to classify and manage recipes that exist in plural form.

### (Selection Step S1101 of Optical Conditions)

Optical conditions used in performing the length measurement are selected. Parameters for the optical conditions are a probe current incident on the sample, the field of view at the time of imaging, the incident energy, and the electrical field intensity formed on the sample. Upon the acquisition of the SEM image, they are determined so as to avoid the occurrence of “deterioration of image quality of SEM in multiple image acquisitions such as frame addition” and “abnormal contrast such as uneven brightness harmful on the length measurement”. Upon this work, the operator may arbitrarily select an optical condition, or a manufacturer determines the recommended conditions upon device shipments. It may be used therefor.

### (Registration Step S1102 for Alignment)

In the sample such as the semiconductor wafer formed with the pattern, there is a need to accurately measure the positional relationship between the coordinates of the stage 116 for moving the sample and the coordinates of the pattern formed on the sample. In the present embodiment, the process of measuring this positional relationship is assumed to be an alignment process. Here, the image of the pattern on the sample, which is recognizable on the optical image and SEM image, is registered in the external server as a template. The template may be registered with the external storage device being connected to the length measurement system control unit 137.

Two kinds of optical and SEM images can be registered in the template. The template for the optical image is used for a first alignment process step, and the template for the SEM image is used for a second alignment process. There is typically used a procedure for performing the second alignment process high in precision through the first alignment process low in precision.

For example, the registration operation is performed by the device operator to select the optical image and SEM image to be displayed on the image display unit 135.

### (Registration Step S1103 of Alignment Position)

In order to accurately correct the positional relationship between the coordinates of the stage 116 and the coordinates of the pattern formed on the sample, there is a need to perform the alignment process in at least two places.

The registration of each location to be aligned is performed here. The registration is performed by the device operation to select the proper position on the SEM image displayed on the image display unit 135, for example.

### (Execution Step S1104 of Alignment)

Here, the positional relationship between the coordinates of the stage 116 and the coordinates of the patter of the sample is measured from an image comparison between the optical image and SEM image taken by templates and the location registered above.

### (Template Registration Step S1105 for Measurement Position Retrieval)

Next, a position retrieval template for searching the location to be measured is registered in the vicinity of the pattern to be length-measured. As with the templates for alignment, the template for the measurement position retrieval is stored in the external server, but templates may be registered by connecting the external storage device to the length measurement system control unit 137.

The registration operation itself is performed in the same manner as at the time of registration of the template for alignment. Information to be registered as a template an SEM image of low magnification and a stage coordinate. After moving to the registered stage coordinates, the process for searching a point to be measured determines a location by capturing or imaging an SEM of a low magnification and performing pattern matching with the registered image.

### (Register Template at Measurement Point: S1106)

After registering the template for the above measurement position retrieval, a template at a point to be length-measured is registered in the external server. Here, as the image to be registered as a template, the image of substantially the same magnification as the imaging magnification of the SEM at the time that the dimension of the pattern is measured, is registered. Tasks to be performed at the time of registration are the same as the registration work of the template for alignment and the template for measurement position retrieval.

### (Decision Step S1107 as to Whether or not Energy Filter is Necessary)

When the use of the energy filter is necessary for the sample to be length-measured, the setting of the energy filter is performed in accordance with the following procedure. When the use of the energy filter is not required, the procedure flies to an image acquisition process (implementation of length measurement) of step S1109 shown in FIG. 11. Whether or not to use the energy filter is determined by the operator and can also be set freely. The device may however automatically determine whether or not to use the energy filter from the basic information of the sample described above.

There are two types as ways to automatically make decisions by the device. One is a method that refers to a recipe created in the past and determines by the device whether or not the use of the energy filter is necessary. While the recipe is stored in the external server, the external storage device separate from the server may be connected to the length measurement system control unit 137. Alternatively, the length measurement system control unit 137 or other device elements may be provided with storage means such as a memory to store the recipe therein. The length measurement system control unit 137 calls the recipe from the external server and/or the external storage device in accordance with the basic information of the sample input by the device operator and refers to it.

Another is a method that the manufacturer of the device causes the device to store a correspondence table about the necessity of energy filter use upon the shipment of the SEM type length measuring device and determines by the device whether or not to use the energy filter, on the basis of the correspondence table. For example, when the sample is a semiconductor wafer, the structure and material of the wafer surface are reflected on the name of the process. Therefore, a correspondence table of energy filter use conditions recommended by the manufacturer is created for each name and stored in the device.

When this method is implemented in the actual device, for example, a correspondence table is stored by connecting an external storage device to the length measurement system control unit 137. The length measurement system control unit 137 refers to the above correspondence table with the name of the manufacturing process input by the device operator as a lookup key and determines whether or not the use of the energy filter is necessary for samples manufactured by the manufacturing process. In the case of each device having adopted the present method, it is necessary to update the correspondence table each time a new manufacturing process is developed. Therefore, a portable recording medium is used as an external storage device, and the correspondence table is stored in the portable recording medium.

As a result of this, since the correspondence table can be updated simply by replacing the recording medium at the time of renewal of the correspondence table, the updating operation is facilitated. Alternatively, if the entire length measuring system is configured in such a manner that a new correspondence table is stored in the external server and can be downloaded from the server upon updating the correspondence table, the updating operation of the correspondence table is further facilitated. Incidentally, here the “length measuring system” means a system configured by the SEM type length measuring device, the external server and a communication line and includes other system elements within a range related to the length measurement.

### (Setting Step S1108 of Energy Filter)

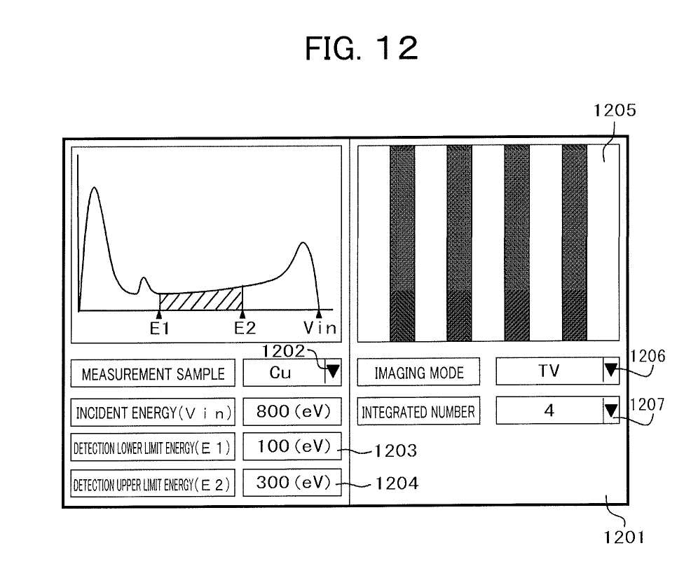

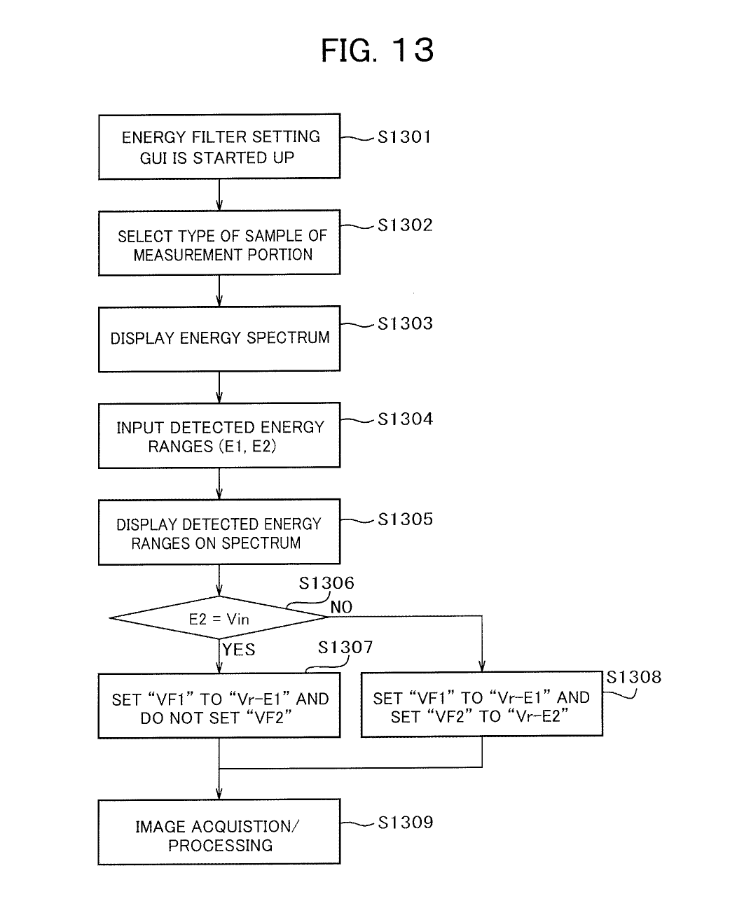

A method of setting the use conditions of the energy filter will be described using a GUI 1201 shown in FIG. 12 and a flowchart shown in FIG. 13. When the energy filter is used, the GUI 1201 shown in FIG. 12 is newly displayed on the image display unit 135 (S1301).

First, a button (A) 1202 that can select the information stored in the device in a pull-down function is pressed to select the type of sample targeted for length measurement from among the options (S1302). The length measurement system control unit 137 calls the energy dependence of the number of signal electrons (secondary electrons, backscattered electrons and Auger electrons) from the external server and/or the external storage device in accordance with the type of sample input by the device operator and displays it on the GUI 1201 (S1303). The spectrum of the energy dependence of the number of the signal electrons for a typical sample is stored in the external server and/or the external storage device by the manufacturer, but for samples that have not been recorded, the user can add the same later. The above spectrum can be registered in the external server and/or the external storage device, but can also be measured by the SEM type length measuring device shown in FIG. 1.

Here, a method of measuring the above spectrum by the SEM length measuring device will be described. An S curve measured from the signal electrons generated from the sample is such that the spectrum of the energy dependence of the number of the signal electrons, and the transmission function of the energy filter 108 are convoluted. Here, the S curve is obtained by observing the sample while changing the voltage applied to the energy filter 108. Further, the transmission function of the energy filter 108 can be determined, for example, by applying the same voltage as the voltage to accelerate the primary electrons 138 with the electron source 102 to the wafer (sample) 113, and measuring changes in the number of electrons reaching the detector 127 with respect to the voltage applied to the energy filter 108 on the condition that the primary electrons are splashed directly above the wafer 113 and incident on the energy filter 108. This transmission function can also be measured by a user, but the manufacturer may record it in the external server and/or the external storage device in advance. When the S curve and the transmission function are obtained, the spectrum of the energy dependence of the intended number of signal electrons is obtained by convoluting both. This calculation and processing can be executed by the length measurement system control unit 137 and results thereof are stored in the external server and/or the external storage device connected to the length measurement system control unit 137.

When an energy range of signal electrons to form a scan image is input to a detection lower limit energy input unit 1203 and a detection upper limit energy input unit 1204 on the GUI 1201 (S1304), the detected energy range is represented by a diagonally-shaded area on the spectrum. While the present embodiment will describe a method of inputting the energy range of the signal electrons on the GUI 1201, a similar result can be obtained even if the user inputs the energy range by a slide bar or the like.

Here, the input range of detection lower limit energy (E1) is 0≦E1<Vin (Vin: incident energy of primary electron to the wafer). The input range of detection upper limit energy (E2) is E1<E2≦Vin. When E2=Vin at step S1306, a first set voltage VF1 of the energy filter is set to Vr−E1 (Vr: retarding voltage in the first embodiment), and a second set voltage VF2 of the energy filter is set to 0 (S1307). When E2≠Vin at step S1306, the first set voltage of the energy filter is set to VF1, and the second set voltage VF2 is set to Vr−E2 (S1308).

Although described in step (S1309) of image acquisition/processing in detail, an image by signal electrons in an energy range (diagonally-shaded area on the spectrum of GUI 1201) from E1 to E2 is displayed on a scan image display unit 1205 on the GUI 1201 at any time. The imaging system of images to be displayed and the integrated number thereof are respectively selected from among the choices by pressing a button (B) 1206 and a button (C) 1207 capable of selecting the information stored in the device with the pull-down function.

By applying the GUI 1201 and its control/processing function shown in the present embodiment to the SEM type length measuring device, the user is able to observe on the GUI 1201, an image to be formed by the signal electrons in the set energy range in synchronization with the operation of changing the energy range of the detected signal electrons. Thus, the user is able to perform the determination of the optimal energy range in a short time. After the above setting of the energy filter, the procedure proceeds to “image acquisition processing” in FIG. 11.

### (Step S1109 of Image Acquisition/Processing)

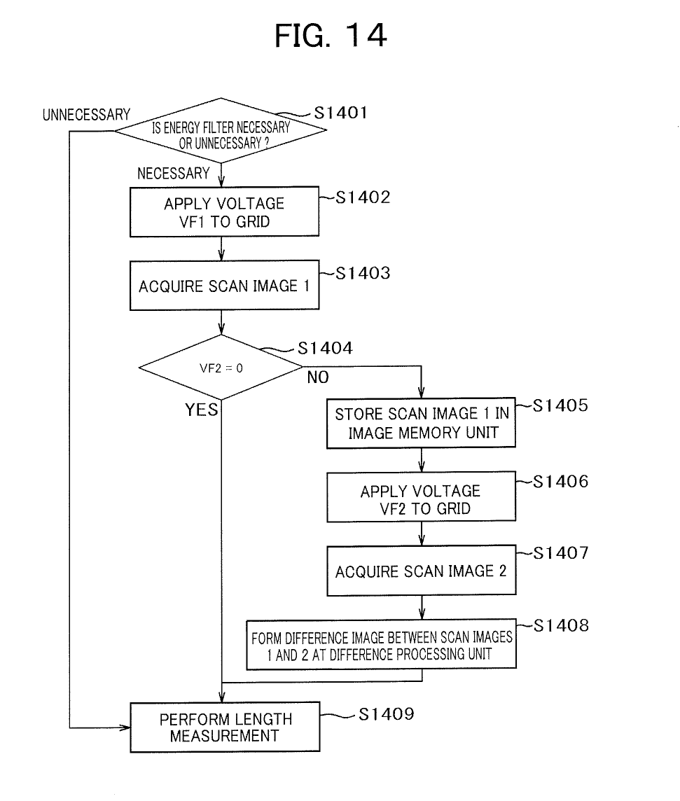

The details of the process performed in the “image acquisition/processing” will be described using a flowchart (FIG. 14). The present flowchart corresponds to steps S1107 through S1109.

First, when the energy filter is not used at a necessity step S1401 of the energy filter, a scan image is obtained on conditions determined in the selection of the optical conditions (step S1101 in FIG. 11), and the flowchart proceeds to step S1409 of “implementation of length measurement”.

When the energy filter is used at the necessity step S1401 of the energy filter, a first set voltage VF1 is first applied to the grid in the energy filter (S1402) to acquire a scan image 1 at that time (S1403). When the set value of VF2 is 0 at step S1404, the “implementation of length measurement” in FIG. 14 is performed using the scan image 1. When the set value of VF2 is not 0 at step S1404, the scan image 1 is stored in the image memory unit (S1405), and a second set voltage VF2 is applied to the grid of the energy filter (S1406) to acquire a scan image 2 (S1407). The difference image processing unit forms a difference image between the scan image 1 and the scan image 2 (Step 1408). The formed difference image is used after the “implementation of length measurement (step S1409)”. The length measurement of a length measurement point is performed on the image obtained at step S1109 of the “image acquisition/processing”, and the device stores its results therein. The information stored here may be only the length-measured dimensions, but may be stored with being accompanied by the SEM image.

### (Storage Step S1110 of Recipe File)

When the length measurement is being carried out properly, the storage of the file of recipes is performed (step S1110). When the length measurement cannot be performed properly the procedure returns to the “selection of optical conditions (step S1101)” to repeat the same work as above.

### “Process of Automatic Length Measurement”

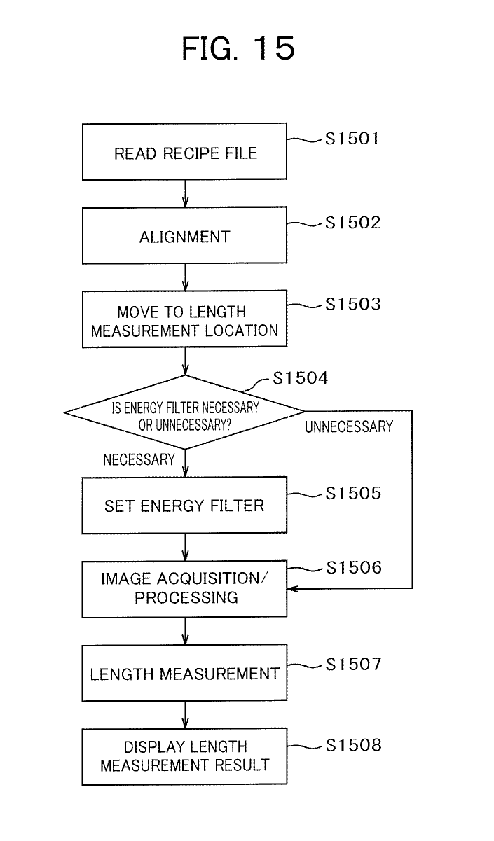

A procedure for automatic length measurement using the recipe by using FIG. 15 is next shown.

Upon the start of the present step, the operator first inputs the basic information of the sample to be length-measured. Based on the input basic information, the device reads the appropriate recipe from the external server and starts the automatic length measurement. Since the length measuring SEM automatically executes the processing of input subsequent to the input of the basic information, based on the recipe, it never bothers the operator.

### (Alignment Step S1502)

Alignment is performed based on the information about the alignment points stored in the recipe to correct the positional relationship between the stage coordinates and the coordinates of the pattern of the sample.

### (Movement Step S1503 to Measurement Position)

A place to be length-measured is searched based on the coordinates recorded as a length measurement retrieval template and the low-magnification image of SEM. When the position coordinates of a point to be length-measured is ascertained, the SEM system control unit 136 moves the stage 116 via the stage control unit 118 in such a manner that the length measurement point on the sample is positioned in the irradiation region of the primary electron beam 138.

### (Decision Step S1504 of Necessity of Energy Filter)—(Setting Step S1505 of Energy Filter)

When information about the necessity of energy filter use recorded in the recipe is read and the use of the energy filter is necessary, the energy filter is set to the conditions of the energy filter recorded in the recipe (S1505), and the procedure moves to step of image acquisition/processing (S1506). When the use of the energy filter is not necessary, the setting of the energy filter is not carried out and the procedure moves to step of image acquisition/processing (S1506).

### (Step S1605 of Image Acquisition/Processing)

The acquisition and different processing of each image are performed on the conditions recorded in the recipe. The obtained image is used in step for length measurement.

### (Step S1507 of Length Measurement)

The length measurement is performed on the image obtained in the step of the image acquisition/processing. As the result of the length measurement, only the dimensions obtained by the length measurement may be stored as with the above (implementation of length measurement), but may be stored with an image attached thereto. Further, it is possible to confirm the result by displaying it on the image display unit 135 (S1508).

When the measurement is finished, the stage 116 moves the sample to the following measuring point and performs the length measurement in the same procedure as above.

By software implementing or hardware implementing steps described above on the SEM type length measuring device, the length measurement accompanied by the use of the energy filter can be realized. In particular, the operation of the energy filter not required can be omitted from the entire length measuring process by storing the recipe necessity determination of the energy filter as the recipe. This brings about an effect in improving the throughput of the length measurement. In particular, a large effect is brought about in the case of providing the length measuring SEM in the mass production line of the semiconductor device fabrication.

As the above software implementation, for example, software for energy filter control is stored in the length measurement system control unit 137 with being provided with a memory and another external storage device therein.

As the hardware implementation, dedicated chips for executing such steps as shown in FIGS. 11 and 15 may be incorporated in the length measurement system control unit.

As a result of measuring the dimensions of the insulator line pattern on the conductor by the length measuring method of the present embodiment using the SEM type length measuring device according to the first embodiment, the boundary between the conductor pattern and the insulator pattern is distinguished clearly, so that high-precision dimensional measurement was made possible

According to the present embodiment as described above, even if it has a retarding optical system, there can be provided a length measurement method capable of high-precision pattern dimensional measurement by using a scanning electron microscope equipped with a deceleration electrical field-type energy filter having a conductor thin film.

### Third Embodiment

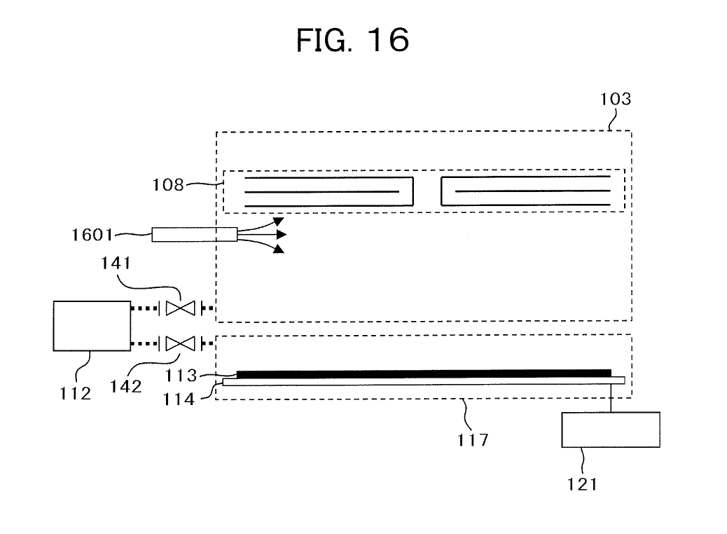

A third embodiment will be described using FIG. 16. Incidentally, matters described in the first and second embodiments and not described in the present embodiment can be applied even to the present embodiment unless otherwise specified. FIG. 16 is a schematic fragmentary configuration diagram of the SEM type length measuring device according to the present embodiment.

In the SEM type length measuring device (FIG. 1) shown in the first embodiment, the signal electrons constantly collide with the conductor thin film 304 of the energy filter 108. Therefore, when it is used for a long time, contaminants principally composed of carbon (hereinafter described as contami) are adhered to the conductor thin film 304. Carbon adhered as contami has an insulating property. When the contami having the insulating property are adhered thereto, the uniformity of the potential barrier formed on the conductor thin film 304, of the energy filter 108 is deteriorated due to the charging of the contami, and hence the energy resolution is degraded.

Thus, as to the deceleration electrical field-type energy filter 108 using the conductor thin film mounted in the SEM type length measuring device (FIG. 1) shown in the first embodiment, there is a need to automatically remove the contami adhered to the conductor thin film 304 or perform the replacement of the conductor thin film 304 in order to use while maintaining its performance. When the conductor thin film with the contami adhered thereto is replaced, it becomes a large burden for the operator because it is necessary to disassemble the SEM housing 103.

Therefore, in the present embodiment, there is provided with respect to the SEM type length measuring device (FIG. 1), a method of automatically removing the contami adhered to the conductor thin film 304 of the energy filter 108 section and using the device in maintenance-free form. The present embodiment can be realized by simply adding a gas supply unit 1601 shown in FIG. 16 to the SEM type length measuring device (FIG. 1) shown in the first embodiment.

A method of removing the carbon as the contami adhered to the conductor thin film will be described using FIG. 16. The contami removing method to be described below has been set to the length measurement system control unit 137 in such a manner as to be done automatically when the operating time of the device exceeds a certain constant time (e.g., 1,000 hours). It is also possible for a user to select the implementation of contami removal manually.

First of all, the valve (A) 141 and the valve (B) 142 that connect the SEM housing 103, the sample chamber 117 and the vacuum pumping system unit 112 are closed. Next, the ozone gas is introduced from the gas supply unit 1601. Carbon principally composed of ozone and contami reacts as follows and is withdrawn from the surface of the conductor thin film 304.

C+O₃→CO+O₂

As the above reaction proceeds sufficiently, the introduction of ozone gas is stopped, and the valve (A) 141 and the valve (B) 142 that connect the SEM housing 103 and the sample chamber 117 and vacuum pumping system unit 112 are opened to exhaust the gas separated from the conductor thin film 304 and to return the SEM housing 103 and the sample chamber 117 to vacuum. Incidentally, it is needless to say that when C and graphene are used as a conductor thin film, the treatment time is adjusted so as to stop the above reaction when only the insulative carbon has been removed. Further, although the present embodiment has described an example of using ozone as the gas used in the removal of the contami, other gases with a contami removing function, for example, activated oxygen can be used instead of ozone gas. The contami removing method described in the present embodiment makes it possible to realize an SEM type length measuring device equipped with a maintenance-free energy filter.

As a result of measuring the dimensions of the insulator line pattern on the conductor by the length measuring method of the second embodiment, using the SEM type length measuring device according to the embodiment 3, the boundary between the conductor pattern and the insulator pattern is distinguished clearly, and hence high-precision dimensional measurement was made possible.

According to the present embodiment as described above, an effect similar to the first and second embodiments can be obtained. By performing the removal of contami adhered to the conductor thin film, a maintenance-free scanning electron microscope and a length measuring method using it can be provided.

### Fourth Embodiment

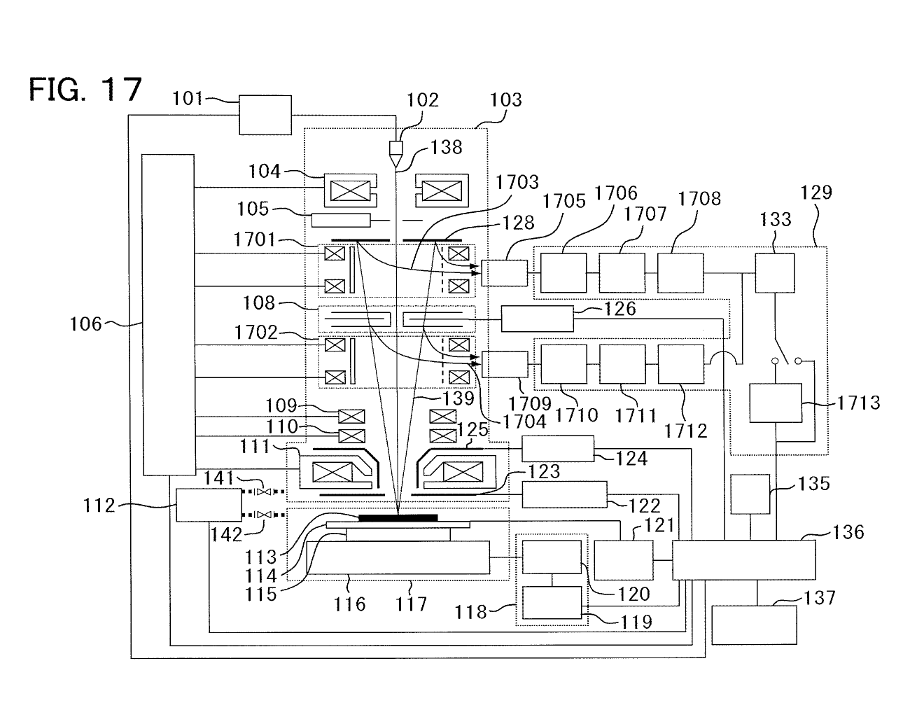

A fourth embodiment will be described using FIG. 17. Incidentally, matters described in any of the first through third embodiments and not described in the present embodiment can be applied even to the present embodiment unless otherwise specified.

In the present embodiment, a configuration example of an SEM type length measuring device to which a deceleration electrical field-type energy filter using a conductor thin film, especially an SEM type length measuring device equipped with detectors of signal electrons above and below the above energy filter will be described. A schematic overall configuration diagram of a scanning electron microscope (SEM type length measuring device) according to the present embodiment is shown in FIG. 17.

In the SEM type length measuring device described in the present embodiment, a detector (B) 1709 is provided below the energy filter 108 thereby to make it possible to detect tertiary electron (B) 1704 generated by signal electrons 139 that have collided with the energy filter 108. The aforementioned tertiary electrons are those that have been lost without being detected in the SEM type length measuring device shown in FIG. 1. The secondary electrons among the signal electrons that have collided with the filter mainly are generated. Thus, the SEM type length measuring device described in the present embodiment can simultaneously detect the signal electrons having passed through the energy filter with a negative voltage applied thereto, for example, the backscattered electrons, and the secondary electrons having collided with the filter and bring them to imaging.

Broadly speaking, the SEM type length measuring device is comprised of an SEM housing 103, a sample chamber 117, an SEM system control unit 136, a vacuum pumping system unit 112, an image forming unit 129 and a length measurement system control unit 137. Here, since the sample chamber 117, the SEM system control unit 136, the vacuum pumping system unit 112, and the length measurement system control unit 137 are identical in configuration and function to those shown in FIG. 1, description thereof is omitted.

### (SEM Housing and Sample Chamber)

The SEM housing 103 is made up of an irradiation system for applying a primary electron 138 to a sample and a detection system. The SEM housing 103 is comprised of an electron source 102, a condenser lens 104, an aperture 105, a reflection plate 128, a detector (A) 1705, a detector (B) 1709, an ExB deflector (A) 1701, an ExB deflector (B) 1702, an energy filter 108, deflectors 109 and 110, a booster electrode 125, an objective lens 111 and a trap plate electrode 123.

The primary electrons 138 emitted from the electron source 102 are converged by the condenser lens 104, pass through the aperture 105 for controlling the current of the primary electrons 138 incident on a wafer 113, pass through holes of the reflection plate 128 and a shield pipe of the energy filter 108 and are deflected by the deflectors 109 and 110, followed by being narrowed down by the objective lens 111 and launched into the sample.

In the SEM type length measuring device of the present embodiment, the ExB deflector (A) 1701 and the deflector (A) 1705 are installed on the reflector side than the energy filter 108. The ExB deflector (B) 1702 and the deflector (B) 1709 are placed on the objective lens 111 side than the energy filter 108.

The signal electrons 139 (secondary electrons, backscattered electrons and Auger electrons) generated due to the irradiation of the wafer 113 with the primary electrons 138 are accelerated by a negative voltage applied to a wafer holder 114 by a retarding power supply 121 and the difference in potential between the trap plate electrode 123 and the booster electrode 125 and converged by the objective lens 111. After the signal electrons 139 have been deflected by the deflectors 109 and 110, they pass through the energy filter 108 and impinge on the reflection plate 128.

Electrons (tertiary electrons (A) 1703) generated by the reflection plate 128 due to the signal electrons 139 having collided with the reflection plate 128 are drawn into the detector (A) 1705 by the ExB deflector (A) 1701. Electrons (tertiary electrons (B) 1704) generated by the energy filer 108 due to the signal electrons 139 having collided with the energy filter 108 are drawn into the detector (B) 1709 by the ExB deflector (B) 1702.

An effect can be obtained that the signal electrons 139 are raised to the reflection plate 128 side by applying a positive voltage to the booster electrode 125 from a booster power supply 124. Further, the potential of the booster electrode 125 is prevented from leaking onto the wafer (sample) 113, and the same voltage as the retarding voltage is applied to the trap plate electrode 123 from a trap plate power supply 122 for the purpose of uniformizing charging of the wafer 113 to be charged.

### (Electron Optical System Control Power Supply)

An electron optical system control power supply 106 controls the current of the primary electrons 138 passing through the aperture 105 by controlling the current flowing through a coil that constitutes the condenser lens 104. Further, the electron optical system control power supply 106 controls the current of a coil constituting each of the ExB deflector (A) 1701 and the ExB deflector (B) 1702 and the voltage of the electrode thereof to thereby make it possible to draw the tertiary electrons (A) 1703 and tertiary electrons (B) 1704 into the detectors (A) 1705 and detector (B) 1709 without the primary electrons 138 being deflected at the ExB deflector (A) 1701 and the ExB deflector (B) 1702. Further, the electron optical system control power supply 106 controls the current flowing through coils that constitute the deflectors 109 and 110 to scan the primary electrons 138 on the wafer 113.

The electron optical system control power supply 106 controls the current flowing through a coil constituting the objective lens 111 in such a manner that the primary electrons 138 are focused on the wafer 113. This control is performed in such a manner that the primary electrons 138 are always narrowed down on the wafer 113 when the electron gun power supply 101, the booster power supply 124, the trap plate power supply 122 and the retarding power supply 121 have changed.

The energy of the primary electrons 138 incident on the wafer 113 is determined by the difference between an acceleration voltage set by the electron gun power supply 101 and the voltage (retarding voltage) applied to the wafer holder 114 by the retarding power supply 121. Changing the retarding voltage enables the energy of the primary electrons 138 incident on the wafer 113 to change.

### (Detector and Image Forming Unit)

In order to form a scan image by the signal electrons detected by the detector (A) 1705, the primary electrons 138 are deflected by the deflectors 109 and 110 in such manner that the primary electrons 138 scan on the wafer 113. The signal of the tertiary electrons (A) 1703 captured by the detector (A) 1705 is amplified by a signal amplifier (A) 1706. Thereafter, an AD converter unit (A) 1707 converts the signal into a digital signal and sends the same to an image processing unit (A) 1708. The image processing unit (A) 1708 forms a scan image as a map of a tertiary electron signal synchronized with a scanning signal. The formed scan image is stored in an image memory unit 133.

Likewise, in order to form a scan image by the signal electrons detected by the detector (B) 1709, the primary electrons 138 are deflected by the deflectors 109 and 110 in such manner that the primary electrons 138 scan on the wafer 113. The signal of the tertiary electrons (B) 1704 captured by the detector (B) 1709 is amplified by a signal amplifier (B) 1710. Thereafter, an AD converter unit (B) 1711 converts the signal into a digital signal and sends the same to an image processing unit (B) 1712. The image processing unit (B) 1712 forms a scan image as a map of a tertiary electron signal synchronized with a scanning signal. The formed scan image is stored in the image memory unit 133. The detector (A) 1705 and the detector (B) 1709 are kept floating at a high voltage of positive polarity.

A difference/synthesis processing unit 1713 has a function of forming a difference image between the arbitrary two sheets of scan images stored in the image memory unit 133 and a composite image thereof. As described in the second embodiment, the difference/synthesis processing unit 1713 can form a difference image between a scan image A1 obtained by the detector (A) 1705—image processing unit (A) 1708 when a first set voltage VF1 (<0) is applied to the energy filter 108, and a scan image A2 obtained by the detector (A) 1705—image processing unit (A) 1708 when a second set voltage VF2 (<0) is applied thereto. The difference image is formed by signal electrons having an energy from −VF1 to −VF2.

In addition, the difference/synthesis processing unit 1713 can create a composite image of a scan image A obtained by the detector (A) 1705—image processing unit (A) 1708, and a scan image B obtained by the detector (B) 1709—image processing unit (B) 1712. This becomes effective when a voltage is not applied to the energy filter 108. This is because even when the voltage is not applied to the energy filter 108, signal electrons of a fixed percentage collide with conductor meshes (grids) 301, 302 and 303 and a conductor thin film 304, so that the electrons that can reach the reflection plate 128 are small in number compared with the case where the energy filter 108 is not mounted. As a result, when the energy filter 108 is mounted, but the SEM type length measuring device is used without applying a voltage, the S/N of the image is degraded, thereby resulting in degradation in the reproducibility of length measurement and a reduction in throughput.

As shown in the present embodiment, by detecting the tertiary electrons (B) 1704 generated by the collision with the energy filter 108 by means of the ExB deflector (B) 1702 and the detector (B) 1709, the S/N equivalent to the SEM type length measuring device free of being equipped with the energy filter 108 can be maintained even when using the SEM type length measuring device without applying a voltage to the energy filter 108.

The scan image stored in the image memory unit 133, and the difference image and the composite image formed by the difference/synthesis processing unit 1713 can be confirmed at any time by the user at the image display unit 135 via the SEM system control unit 136.

As a result of measuring the dimensions of the insulator line pattern on the conductor by the length measuring method of the second embodiment, using the SEM type length measuring device according to the present embodiment, the boundary between the conductor pattern and the insulator pattern is distinguished clearly, and hence high-precision dimensional measurement was made possible.

According to the present embodiment as described above, an effect similar to the first and second embodiments can be obtained. Further, by mounting the detectors above and below the energy filter, the S/N equivalent to the SEM type length measuring device free of being equipped with the energy filter 108 can be maintained even when using the SEM type length measuring device without applying a voltage to the energy filter.

Incidentally, the present invention is not limited to the embodiments described above and includes various modifications. For example, the above embodiments are those which have been described in detail in order to make it easier to illustrate the invention and are not necessarily intended to be limited to those having all configurations described. A part of the configuration of a certain embodiment can also be replaced with the configuration of another embodiment. Also, the configuration of another embodiment can be added to the configuration of the certain embodiment. Also, for some of the configuration of each embodiment, it is possible to perform addition, removal and replacement of other configurations.

### EXPLANATION OF REFERENCE NUMERALS

101 . . . electron gun power supply, 102 . . . electron source, 103 . . . SEM housing, 104 . . . condenser lens, 105 . . . aperture, 106 . . . electron optical system control power supply, 107 . . . ExB deflector, 108 . . . energy filter, 109 . . . defector (A), 110 . . . deflector (B), 111 . . . objective lens, 112 . . . vacuum pumping system unit, 113 . . . wafer, 114 . . . wafer holder, 115 . . . insulating material, 116 . . . stage, 117 . . . sample chamber, 118 . . . stage control unit, 119 . . . stage controller, 120 . . . stage driving unit, 121 . . . retarding power supply, 122 . . . trap plate power supply, 123 . . . trap plate electrode, 124 . . . booster power supply, 125 . . . booster electrode, 126 . . . energy filter power supply, 127 . . . detector, 128 . . . reflection plate, 129 . . . image forming unit, 130 . . . signal amplifier, 131 . . . AD converter unit, 132 . . . image processing unit, 133 . . . image memory unit, 134 . . . difference processing unit, 135 . . . image display unit, 136 . . . SEM system control unit, 137 . . . length measurement system control unit, 138 . . . primary electron, 139 . . . signal electron, 140 . . . tertiary electron, 141 . . . valve (A), 142 . . . valve (B), 201 . . . conductor grid, 202 . . . equipotential line, 301 . . . conductor grid, 302 . . . conductor grid, 303 . . . conductor grid, 3, 304 . . . conductor thin film, 501 . . . secondary electron, 502 . . . backscattered electron, 503 . . . Auger electron, 601 . . . insulator, 602 . . . conductor, 603 . . . secondary electron emitted from insulator, 604 . . . secondary electron emitted from conductor, 701 . . . energy dependence of the number of secondary electrons emitted from conductor, 702 . . . energy dependence of the number of secondary electrons emitted from insulator, 1001 . . . shield pipe, 1201 . . . GUI, 1202 . . . button (A), 1203 . . . detection lower limit energy input unit, 1204 . . . detection upper limit energy input unit, 1205 . . . scan image display unit, 1206 . . . button (B), 1207 . . . button (C), 1601 . . . gas supply unit, 1701 . . . ExB deflector (A), 1702 . . . ExB deflector (B), 1703 . . . tertiary electron (A), 1704 . . . tertiary electron (B), 1705 . . . detector (A), 1706 . . . signal amplifier (A), 1707 . . . AD converter unit (A), 1708 . . . image forming unit (A), 1709 . . . detector (B), 1710 . . . signal amplifier (B), 1711 . . . AD converter unit (B), 1712 . . . image forming unit (B), 1713 . . . difference/synthesis processing unit

1. A scanning electron microscope comprising an electron source, a deflector for deflecting a primary electron beam emitted from the electron source, a condenser lens for converging the primary electron beam deflected by the deflector, an electron detector for detecting signal electrons emitted due to irradiation of a sample with the primary electron beam converted by the condenser lens, and a deceleration electrical field-type energy filter which is placed on the sample side than the electron detector and discriminates the energy of the signal electrons,
wherein the deceleration electrical field-type energy filter has a conductor thin film for energy discrimination of the signal electrons.

2. The scanning electron microscope according to claim 1, further comprising deceleration means for decelerating the primary electron beam applied to the sample.

3. The scanning electron microscope according to claim 1, wherein the conductor thin film has at least any of C, graphene, Al, Au, Cu and W, and the thickness thereof is in the range of greater than or equal to 0.3 nm and less than or equal to 50 nm.

4. The scanning electron microscope according to claim 1, wherein the conductor thin film is a multilayer film of an insulator and a conductor, and the thickness thereof is in the range of greater than or equal to 0.3 nm and less than or equal to 50 nm.

5. The scanning electron microscope according to claim 1, wherein the conductor thin film has a number of holes, and a number of the holes allows the signal electrons emitted from the sample to pass therethrough.

6. The scanning electron microscope according to claim 5, wherein a number of the holes have a diameter of 10 μm or less.

7. The scanning electron microscope according to claim 1, wherein the conductor thin film has at least one aperture, and the aperture allows the primary electron beam to pass therethrough.

8. The scanning electron microscope according to claim 1, wherein the aperture has a diameter of 1±0.5 mm.

9. The scanning electron microscope according to claim 7, wherein a shield pipe through which the primary electron beam passes is disposed inside the aperture, and the shield pipe is grounded.

10. The scanning electron microscope according to claim 1, further comprising a user interface for inputting a set voltage to be applied to the conductor thin film.

11. The scanning electron microscope according to claim 1, further comprising an image processing circuit which forms a difference image between a first scan image obtained in a state in which a first set voltage is applied to the conductor thin film, and a second scan image obtained in a state in which a second set voltage is applied to the conductor thin film.

12. The scanning electron microscope according to claim 1, further comprising a second electron detector on the sample side than the conductor thin film, and in that the second electron detector detects electrons emitted due to collision of the signal electrons emitted from the sample with the conductor thin film.

13. The scanning electron microscope according to claim 1, further comprising a gas supply system of ozone or active oxygen for removing contaminants attached to the surface of the conductor thin film, and in that the gas supply system is disposed between the electron detector and the sample.

14. The scanning electron microscope according to claim 1, wherein the deceleration electrical field-type energy filter has first and second conductor grids provided with the conductor thin film interposed therebetween, and
the first and second conductor grids are grounded.

15. The scanning electron microscope according to claim 1, wherein the conductor thin film is located at the sample side end portion of the conductor grid.

16. A length measuring method using a scanning electron microscope according to claim 11, comprising the steps of:
applying a first voltage to the conductor thin film and obtaining a first image, based on the signal electrons energy-discriminated at the first voltage;
applying a second voltage to the conductor thin film and obtaining a second image, based on the signal electrons energy-discriminated at the second voltage;
forming a difference image between the first image and the second image; and
measuring a pattern dimension of the sample from the difference image,
the length measuring method being characterized in that the difference image is formed by Auger electrons of the sample.
